(19) United States
(12) Patent Application Publication
(10) Pub. No.: US 2024/0292513 A1
(43) Pub. Date: Aug. 29, 2024

(54) CIRCUIT STRUCTURE

(71) Applicant: Sumitomo Wiring Systems, Ltd., Yokkaichi-shi, Mie (JP)

(72) Inventor: Hideki GOTO, Yokkaichi-shi, Mie (JP)

(73) Assignee: Sumitomo Wiring Systems, Ltd., Yokkaichi-shi, Mie (JP)

(21) Appl. No.: 18/569,878

(22) PCT Filed: May 27, 2022
(86) PCT No.: PCT/JP2022/021672

§ 371 Date: Dec. 13, 2023

(30) Foreign Application Priority Data
Jun. 16, 2021 (JP) 2021-100255

(51) Int. Cl. H05K 1/02

(52) U.S. Cl. CPC H05K 1/0204; H05K 2201/066; H05K 2201/10272

(57) ABSTRACT

A circuit structure that is for a vehicle and includes a relay having a plurality of terminals is provided. The circuit structure includes an insulating plate member, the relay being mounted on one surface of the insulating plate member, and a first heat dissipation plate member provided on the other surface of the insulating plate member. The insulating plate member is provided with a first through hole in which a first busbar connected to a first terminal of the relay is housed. The first busbar is in contact with the first heat dissipation plate member.

### CROSS-REFERENCE TO RELATED APPLICATIONS

This application is the U.S. national stage of PCT/JP2022/021672 filed on May 27, 2022, which claims priority of Japanese Patent Application No. JP 2021-100255 filed on Jun. 16, 2021, the contents of which are incorporated herein.

### TECHNICAL FIELD

The present disclosure relates to a circuit structure that includes a busbar.

### BACKGROUND

Conventionally, circuit structures that include a circuit in which a busbar is used to allow a relatively large electric current to flow are mounted in vehicles. In recent years, with the extension of vehicle functions, the value of an electric current used has also been increasing.

JP 2014-79093A discloses a power supply apparatus that includes a relay having a contact point capable of being opened and closed and an exciting coil for switching the state of the contact point between an open state and a closed state and that has a configuration in which the contact point is electrically connected to a busbar, the busbar is provided with a heat dissipating mechanism, and thus the busbar can serve as both an electric current path and a heat dissipating path.

The electric resistance increases in proportion to an increase in the value of an electric current used, which leads to an increase in an amount of heat radiated by the circuit element and the busbar. To address this, it is common to increase the width or thickness of the busbar in order to improve the heat dissipation properties.

However, it is difficult to process a busbar having a large width or thickness, and therefore, there is a problem of a difficulty in mass production, a high processing cost, and a low yield.

However, in the case of the power-supply apparatus according to JP 2014-79093A, such a problem is not taken into consideration and cannot be solved.

Therefore, it is an object of the present disclosure to provide a circuit structure whose heat dissipation properties can be improved without increasing the width or thickness of the busbar.

### SUMMARY

A circuit structure according to an embodiment of the present disclosure is a circuit structure that is for a vehicle and includes a circuit element having a plurality of terminals, the circuit structure including: an insulating plate member, the circuit element being mounted on one surface of the insulating plate member; and a first heat dissipation plate member provided on the other surface of the insulating plate member, wherein the insulating plate member is provided with a first through hole in which a first busbar connected to a first terminal of the circuit element is housed, and the first busbar is in contact with the first heat dissipation plate member.

### Advantageous Effects

With the present disclosure, it is possible to improve heat dissipation properties without increasing the width or thickness of the busbar.

### BRIEF DESCRIPTION OF DRAWINGS

FIG. 1 is a perspective view illustrating an example of a circuit structure of Embodiment 1.

FIG. 2 is a perspective view showing the circuit structure of Embodiment 1 as viewed from the other surface side of an insulating plate member.

FIG. 3 is an exploded view of the circuit structure of Embodiment 1.

FIG. 4 is a cross-sectional view taken along line IV-IV in FIG. 1.

FIG. 5 is a perspective view illustrating an example of a circuit structure of Embodiment 2.

FIG. 6 is a perspective view showing the circuit structure of Embodiment 2 as viewed from the other surface side of an insulating plate member.

FIG. 7 is an exploded view of the circuit structure of Embodiment 2.

FIG. 8 is a perspective view showing the circuit structure of Embodiment 2, in which a portion of the circuit structure is omitted.

FIG. 9 is a perspective view showing Modified Example 1 of the circuit structure of Embodiment 2.

FIG. 10 is a perspective view showing Modified Example 2 of the circuit structure of Embodiment 2.

### DETAILED DESCRIPTION OF PREFERRED EMBODIMENTS

First, aspects of the present disclosure will be listed and described. Also, at least portions of the aspects described below may be optionally combined.

A circuit structure according to an aspect of the present disclosure is a circuit structure that is for a vehicle and includes a circuit element having a plurality of terminals, the circuit structure including: an insulating plate member, the circuit element being mounted on one surface of the insulating plate member; and a first heat dissipation plate member provided on the other surface of the insulating plate member, wherein the insulating plate member is provided with a first through hole in which a first busbar connected to a first terminal of the circuit element is housed, and the first busbar is in contact with the first heat dissipation plate member.

In this aspect, the first busbar is housed in the first through hole of the insulating plate member, and the first busbar is in contact with the first heat dissipation plate member. Accordingly, heat radiated by the circuit element is directly transferred to the first heat dissipation member via the first terminal and the first busbar, and is then dissipated.

In the circuit structure according to an aspect of the present disclosure, the insulating plate member is provided with a second through hole, and the first heat dissipation plate member is exposed from the one surface side of the insulating plate member through the second through hole.

In this aspect, the first heat dissipation plate member is exposed from the one surface side of the insulating plate member to the outside through the second through hole. Accordingly, heat radiated by the circuit element is transferred to the first heat dissipation member via the first busbar, and the first heat dissipation member is air-cooled via the second through hole.

In the circuit structure according to an aspect of the present disclosure, the insulating plate member is provided with a recessed portion in which a second busbar connected to a second terminal of the circuit element is installed, on the one surface.

In this aspect, the second busbar is installed in the recessed portion of the insulating plate member. Accordingly, heat radiated by the circuit element is transferred to the second busbar via the second terminal, then transferred to the first heat dissipation member by way of the bottom of the recessed portion, and is then dissipated.

In the circuit structure according to an aspect of the present disclosure, the second busbar is provided with a connection through hole used for connection with the second terminal, a bottom of the recessed portion is provided with a third through hole at a position corresponding to the connection through hole, a rib provided along an edge of the third through hole protrudes from the other surface of the insulating plate member, and the first heat dissipation plate member is provided with a fitting through hole to which the rib is internally fitted.

In this aspect, the third through hole is formed in the bottom of the recessed portion, and the rib of the third through hole is internally fitted to the fitting through hole of the first heat dissipation plate member. Accordingly, even when a screw is inserted through the connection through hole of the second busbar and is used to connect the second busbar and the second terminal, the screw is surrounded by the rib of the third through hole and is insulated from the first heat dissipation plate member.

In the circuit structure according to an aspect of the present disclosure, the first terminal radiates a larger amount of heat than the second terminal during an operation of the circuit element.

In this aspect, in order to address an issue in that the first terminal radiates a larger amount of heat than the second terminal during the operation of the circuit element, the first busbar directly transfers heat radiated by the first terminal to the first heat dissipation member, and the second busbar indirectly transfers heat radiated by the second terminal to the first heat dissipation member via the bottom of the recessed portion. Accordingly, heat radiated by the first terminal, which radiates a larger amount of heat than the second terminal, can be predominantly dissipated.

In the circuit structure according to an aspect of the present disclosure, the insulating plate member is provided with a fourth through hole in which a second busbar connected to a second terminal of the circuit element is housed, a second heat dissipation plate member that comes into contact with the second busbar is housed in the fourth through hole, and an insulating thread is interposed between the first heat dissipation plate member and the second heat dissipation plate member on the other surface of the insulating plate member.

In this aspect, the second busbar is housed in the fourth through hole of the insulating plate member, and the second busbar is in contact with the second heat dissipation plate member. Accordingly, heat radiated by the circuit element is directly transferred to the second heat dissipation member via the second terminal and the second busbar, and is then dissipated. The first heat dissipation member and the second heat dissipation member are insulated from each other by the insulating thread.

In the circuit structure according to an aspect of the present disclosure, the first terminal radiates a larger amount of heat than the second terminal during an operation of the circuit element, and the first heat dissipation plate member is larger in size than the second heat dissipation plate member.

In this aspect, in order to address an issue in that the first terminal radiates a larger amount of heat than the second terminal during the operation of the circuit element, the first heat dissipation member to which heat radiated by the first terminal is transferred via the first busbar is larger in size than the second heat dissipation member to which heat radiated by the second terminal is transferred via the second busbar. Accordingly, heat radiated by the first terminal, which radiates a larger amount of heat than the second terminal, can be predominantly dissipated.

In the circuit structure according to an aspect of the present disclosure, the first heat dissipation plate member has electric conductivity.

In this aspect, in the case of, for example, connecting the first terminals of a plurality of circuit elements in series, the first terminals can be electrically connected via the first heat dissipation plate member because the first heat dissipation plate member has electric conductivity. Accordingly, the first busbar that is interposed between the first terminal and the first heat dissipation plate member can be partially omitted.

Hereinafter, circuit structures according to embodiments of the present disclosure will be described with reference to the drawings. Note that the present disclosure is not limited to these examples, but rather is indicated by the scope of the claims, and is intended to include all modifications within the scope and meaning equivalent to the scope of the claims.

### Embodiment 1

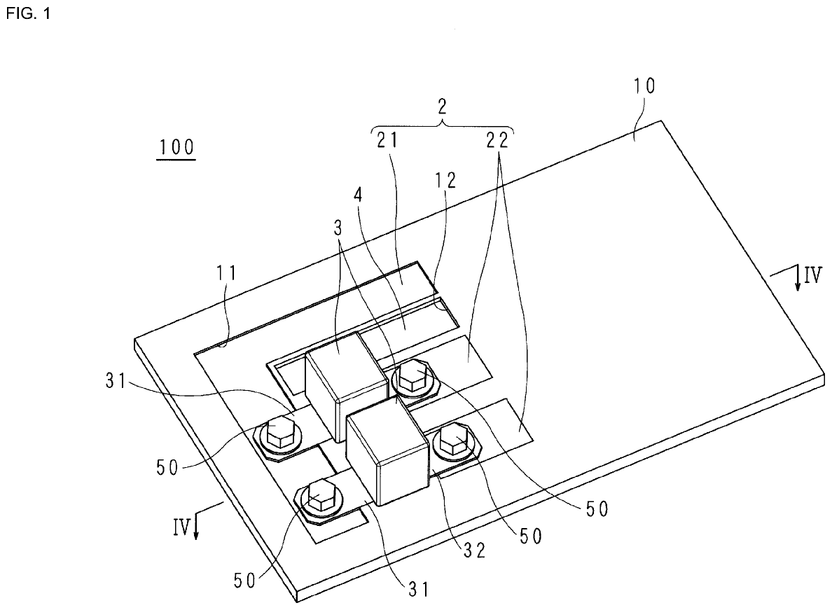

FIG. 1 is a perspective view illustrating an example of a circuit structure 100 of Embodiment 1. The circuit structure 100 is to be mounted in a vehicle. The circuit structure 100 includes, for example, a rectangular insulating plate member 10, and the insulating plate member 10 includes a relay 3 (circuit element) on one surface thereof (two relays 3 are mounted, for example). The insulating plate member 10 is made of an insulating resin.

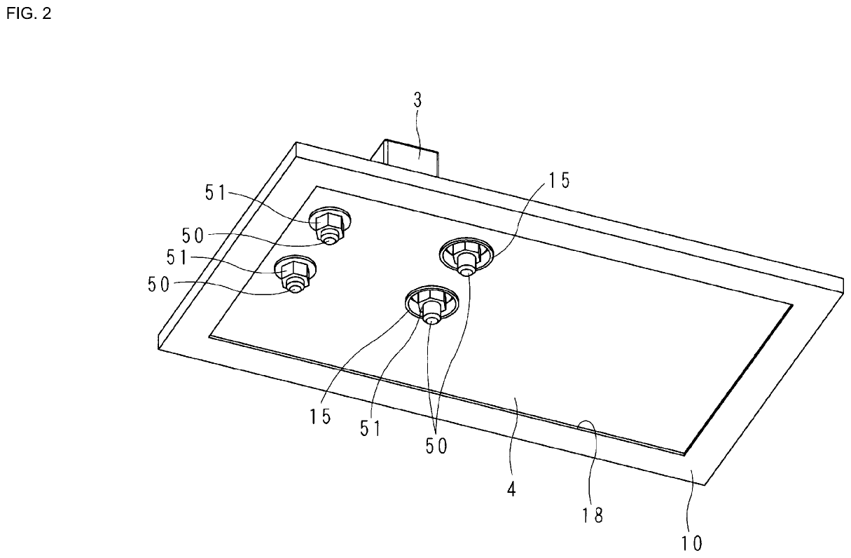

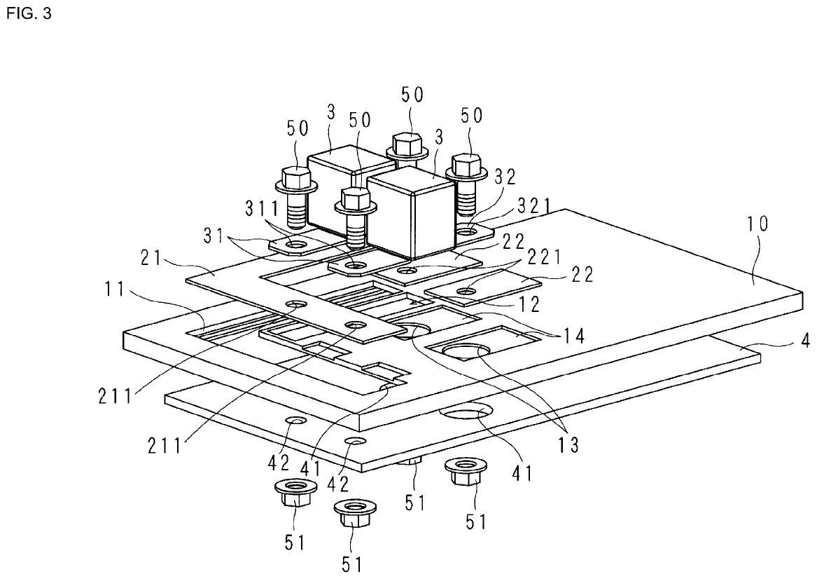

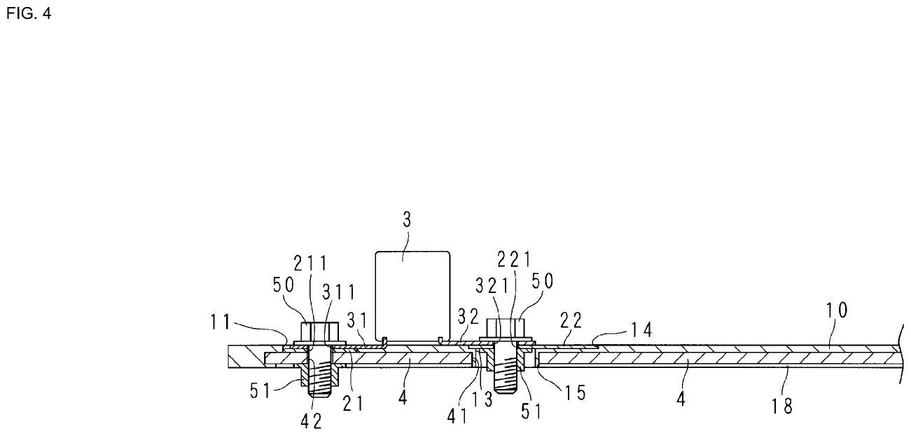

FIG. 2 is a perspective view showing the circuit structure 100 of Embodiment 1 as viewed from the other surface side of the insulating plate member 10, FIG. 3 is an exploded view of the circuit structure 100 of Embodiment 1, and FIG. 4 is a cross-sectional view taken along line IV-IV in FIG. 1.

Each of the relays 3 includes a first terminal 31 and a second terminal 32 that extend along the one surface of the insulating plate member 10 and have a strip shape. For example, the relay 3 is switched to the ON state when a vehicle starts traveling, and the relay 3 is switched to the OFF state when the vehicle stops traveling. During the operation of the relay 3, the first terminal 31 radiates a larger amount of heat than the second terminal 32. The end portions of the first terminal 31 and the second terminal 32 are provided with a through hole 311 and a through hole 321, respectively. The relay 3 is fixed to the insulating plate member 10 using screws via the first terminal 31 and the second terminal 32.

The insulating plate member 10 is provided with busbars 2 connected to the first terminal 31 and the second terminal 32 of the relay 3. The first terminal 31 is connected to a first busbar 21, and the second terminal 32 is connected to a second busbar 22. The first terminals 31 of the two relays 3 are both connected to the first busbar 21. That is to say, the insulating plate member 10 is provided with one first busbar 21 and two second busbars 22. The first busbar 21 and the second busbars 22 are produced using a metal plate material having a good electric conductivity. The first busbar 21 and the second busbars 22 are made of, for example, copper. The first busbar 21 and the second busbars 22 are electrically connected to another circuit element or circuit, which are not shown in FIG. 1.

The insulating plate member 10 is provided with a first through hole 11 that passes therethrough in the thickness direction. The first through hole 11 has a shape corresponding to the shape of the first busbar 21. The first busbar 21 is housed in the first through hole 11 from the one surface side of the insulating plate member 10. That is to say, one surface of the first busbar 21 is exposed from the one surface of the insulating plate member 10. The other surface of the first busbar 21 is in contact with a first heat dissipation plate member 4, which will be described later.

The first busbar 21 is provided with through holes 211 that pass through the first busbar 21 in the thickness direction at positions corresponding to the through holes 311 of the first terminals 31 of the relays 3 (see FIG. 3).

The insulating plate member 10 is provided with a second through hole 12 that passes therethrough in the thickness direction. The second through hole 12 has, for example, a rectangular shape, and is formed in the vicinity of the first terminals 31 of the relays 3. The first heat dissipation plate member 4 is exposed from the one surface of the insulating plate member 10 through the second through hole 12.

As shown in FIG. 3, recessed portions 14 are formed at two positions on the one surface of the insulating plate member 10. Each of the recessed portions 14 has a shape corresponding to the shape of the second busbar 22, and the second busbar 22 is housed in the recessed portion 14. Each of the second busbars 22 is provided with a through hole 221 (connection through hole) that passes through the second busbar 22 in the thickness direction at a position corresponding to the through hole 321 of the second terminal 32 of the relay 3.

The bottom of each of the recessed portions 14 is provided with a third through hole 13 that passes through the insulating plate member 10 in the thickness direction at a position corresponding to the through hole 221 of the second busbar 22. A rib 15 is provided around the edge of the third through hole 13 on the other surface side of the insulating plate member 10 (see FIGS. 2 and 4). In other words, the rib 15 has a cylindrical shape. The through hole 321 of the relay 3, the through hole 221 of the second busbar 22, and the third through hole 13 (rib 15) of the recessed portion 14 are aligned in the thickness direction of the insulating plate member 10. The diameter of the third through hole 13 is the largest, and is larger than the diameter of a nut 51, which will be described later.

As shown in FIG. 2, the insulating plate member 10 is provided with a recessed portion 18 over the substantially entire region on the other surface, and the first heat dissipation plate member 4 is provided in the recessed portion 18. The first heat dissipation plate member 4 has a rectangular shape following the insulating plate member 10, and is slightly smaller than the insulating plate member 10. That is to say, the first heat dissipation plate member 4 covers most of the other surface of the insulating plate member 10, and one surface of the first heat dissipation plate member 4 is exposed from the other surface of the insulating plate member 10. As described above, a portion of the other surface of the first heat dissipation plate member 4 is exposed from the one surface of the insulating plate member 10 through the second through hole 12. The first heat dissipation plate member 4 has electric conductivity and excellent thermal conductivity. For example, the first heat dissipation plate member 4 is made of the same material (copper) as those of the first busbar 21 and the second busbars 22.

The first heat dissipation plate member 4 is provided with through holes 41 (fitting through holes) that pass therethrough in the thickness direction at positions corresponding to the third through holes 13 of the recessed portions 14. The through holes 41 have a larger diameter than the third through holes 13, and the ribs 15 of the third through holes 13 are internally fitted to the through holes 41.

As described above, the other side of the first heat dissipation plate member 4 is in contact with the first busbar 21. The first heat dissipation plate member 4 is provided with through holes 42 that pass therethrough in the thickness direction at positions corresponding to the through holes 211 of the first busbars 21.

At the time of assembly, screws 50 are inserted through the through holes 311 of the first terminals 31 of the relays 3, and are screwed to nuts 51 after passing through the through holes 211 of the first busbar 21 and the through holes 42 of the first heat dissipation plate member 4. In addition, other screws 50 are inserted through the through holes 321 of the second terminals 32 of the relays 3, and are screwed to nuts 51 after passing through the through holes 221 of the second busbars 22 and the third through holes 13 and the ribs 15 of the recessed portions 14.

At this time, the first terminals 31 of the relays 3 are electrically connected to the first busbar 21, and the first busbar 21 comes into contact with the first heat dissipation plate member 4. Also, the second terminals 32 of the relays 3 are electrically connected to the second busbars 22, and the insulating plate member 10 (recessed portions 14) are interposed between the second busbars 22 and the first heat dissipation plate member 4. As described above, the first busbar 21 is in contact with the first heat dissipation plate member 4, and the second busbars 22 are in contact with the nuts 51. However, as shown in FIGS. 2 and 4, the nuts 51 on the second busbars 22 are located inside the ribs 15. Accordingly, a sufficient spatial distance and a sufficient creepage distance are secured between each of the nuts 51 and the first heat dissipation plate member 4, and the nut 51 and the first heat dissipation plate member 4 are insulated from each other.

With the circuit structure 100 of Embodiment 1 configured as described above, when the relays 3 radiate heat during the operation, the heat is transferred to the first busbar 21 and the second busbars 22 via the first terminals 31 and the second terminals 32, respectively.

Since the first heat dissipation plate member 4 is in contact with the first busbar 21, the heat transferred to the first busbar 21 is transferred to the first heat dissipation plate member 4 and is dissipated from the one surface of the first heat dissipation plate member 4 that is air-cooled. Also, the heat transferred to the second busbars 22 is transferred to the first heat dissipation plate member 4 via the insulating plate member 10 (the bottoms of the recessed portions 14), and is dissipated from the one surface of the first heat dissipation plate member 4 that is air-cooled.

As described above, the first heat dissipation plate member 4 has excellent thermal conductivity, and the one surface thereof making up a great portion of the insulating plate member 10 is exposed to the outside, thus making it possible to efficiently dissipate the heat radiated by the relays 3.

Furthermore, a part of the heat transferred to the first heat dissipation plate member 4 via the first busbar 21 and the second busbars 22 is dissipated from the other surface of the first heat dissipation plate member 4 that is air-cooled through the second through hole 12.

In the circuit structure 100 of Embodiment 1, the first terminals 31 are in direct contact with the first heat dissipation plate member 4 via the first busbar 21, and the second terminals 32 are in indirect contact with the first heat dissipation plate member 4 via the insulating plate member 10. Accordingly, heat radiated by the first terminals 31, which radiate a larger amount of heat than the second terminals 32 during the operation of the relays 3, can be predominantly dissipated, thus making it possible to more efficiently dissipate heat radiated by the relays 3.

With the configuration above, there is no need to increase the width or thickness of the busbar in order to improve the heat dissipation properties of the busbar. Accordingly, more busbars can be mounted, the size of the circuit structure 100 can be reduced, and the manufacturing cost of the circuit structure 100 can be reduced.

In the example described above, the first heat dissipation plate member 4 is provided in the recessed portion 18 formed on the other surface of the insulating plate member 10, but there is no limitation to this configuration. For example, the first heat dissipation plate member 4 may be provided on the other surface of the insulating plate member 10 using insert molding.

Also, in the example described above, one second through hole 12 is formed, but there is no limitation to this configuration, and a plurality of second through holes 12 may be formed.

### Embodiment 2

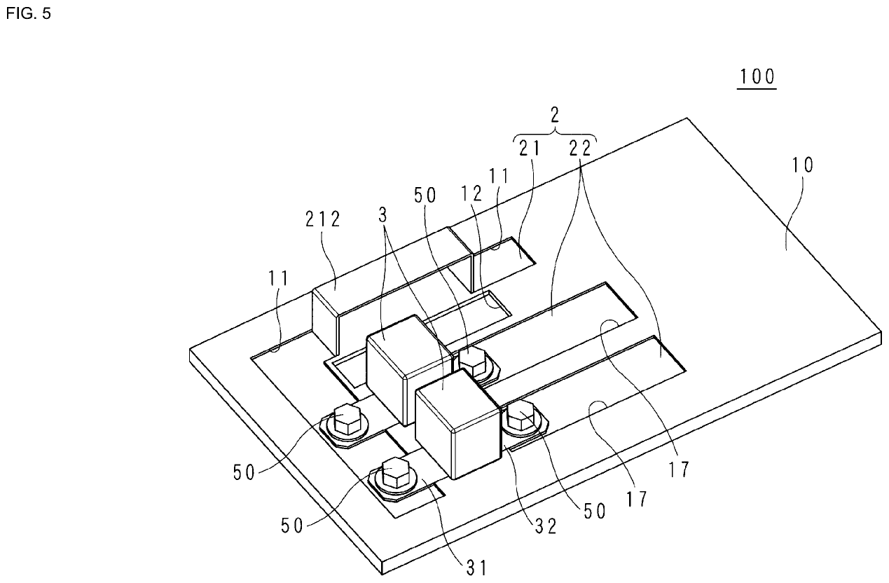

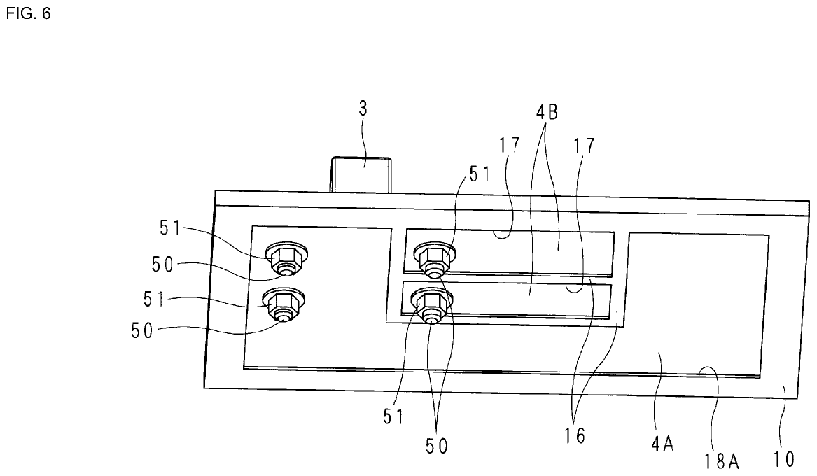

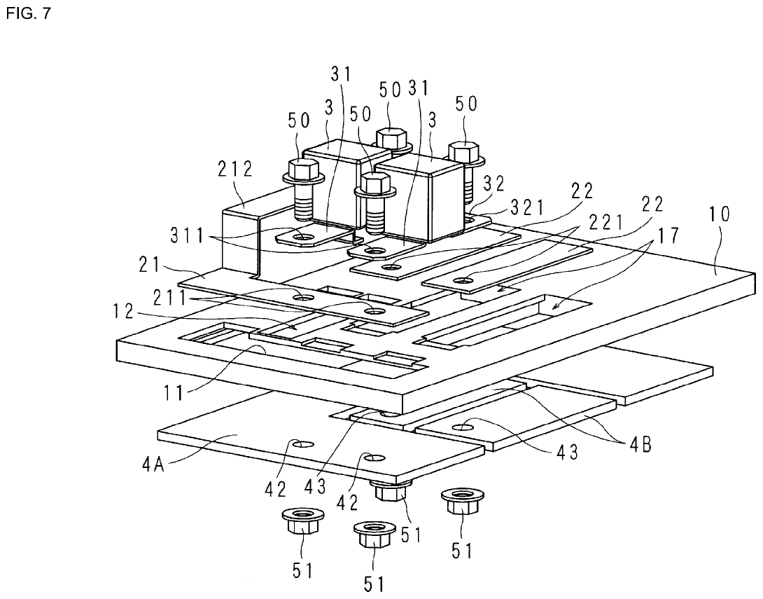

FIG. 5 is a perspective view illustrating an example of a circuit structure 100 of Embodiment 2, FIG. 6 is a perspective view of the circuit structure 100 of Embodiment 2 as viewed from the other surface side of the insulating plate member 10, and FIG. 7 is an exploded view of the circuit structure 100 of Embodiment 2.

As in Embodiment 1, the circuit structure 100 of Embodiment 2 includes the rectangular insulating plate member 10, and two relays 3 are mounted on the one surface of the insulating plate member 10. Each of the relays 3 includes the first terminal 31 and the second terminal 32. The first terminal 31 is connected to the first busbar 21, and the second terminal 32 is connected to the second busbar 22. The insulating plate member 10 is provided with one first busbar 21 and two second busbars 22, the first terminals 31 of the two relays 3 are both connected to the first busbar 21, and the second terminals 32 are connected to different second busbars 22.

In the circuit structure 100 of Embodiment 2, the first busbar 21 includes a bent portion 212 at its intermediate portion, and the bent portion 212 is spaced apart from the one surface of the insulating plate member 10. That is to say, the insulating plate member 10 is provided with the first through hole 11 that passes therethrough in the thickness direction, and the first busbar 21 is housed in the first through hole 11 from the one surface side of the insulating plate member 10. However, the bent portion 212 is not housed in the first through hole 11. Specifically, the bent portion 212 has a substantially inverted U-shape, and its central portion is spaced apart from the one surface of the insulating plate member 10 at a predetermined interval. In the first busbar 21, a portion housed in the first through hole 11 is in contact with the other surface of a first heat dissipation plate member 4A.

The insulating plate member 10 is provided with the second through hole 12 that passes therethrough in the thickness direction, and the first heat dissipation plate member 4A is exposed from the one surface of the insulating plate member 10 through the second through hole 12.

Furthermore, the insulating plate member 10 is provided with fourth through holes 17 at two positions on the one surface. Each of the fourth through holes 17 has a shape corresponding to the shape of the second busbar 22. The second busbar 22 is housed in the fourth through hole 17 from the one surface side of the insulating plate member 10. With this configuration, one surface of the second busbar 22 is exposed from the one surface of the insulating plate member 10, and the other surface is in contact with a second heat dissipation plate member 4B, which will be described later.

As shown in FIG. 6, the insulating plate member 10 is provided with a recessed portion 18A on the other surface, and the first heat dissipation plate member 4A is provided in the recessed portion 18A. The recessed portion 18A has a shape following the first heat dissipation plate member 4A. The recessed portion 18A is provided in a portion of the other surface of the insulating plate member 10, and one surface of the first heat dissipation plate member 4A is exposed from the other surface of the insulating plate member 10. That is to say, the fourth through holes 17 are open in the other surface of the insulating plate member 10, and therefore, the recessed portion 18A is formed in a portion where the fourth through holes 17 are not formed.

A second heat dissipation plate member 4B is housed in each of the fourth through holes 17 from the other surface side of the insulating plate member 10. The second heat dissipation plate member 4B has a shape corresponding to the shape of the fourth through hole 17, and is smaller than the first heat dissipation plate member 4A. The second heat dissipation plate member 4B has excellent thermal conductivity, and is made of, for example, the same material (copper) as those of the first busbar 21 and the second busbars 22. One surface of the second heat dissipation plate member 4B is exposed from the other surface of the insulating plate member 10, and the other surface is in contact with the second busbar 22.

Note that each of the second heat dissipation plate members 4B is provided with a through hole 43 that passes therethrough in the thickness direction at a position corresponding to the through hole 221 of the second busbar 22.

Furthermore, insulating threads 16 for insulation protrude from a portion between the second heat dissipation plate members 4B and the first heat dissipation plate member 4A and a portion between the second heat dissipation plate members 4B on the other surface of the insulating plate member 10. In other words, the insulating threads 16 are provided along the edges of the fourth through holes 17 on the other surface of the insulating plate member 10.

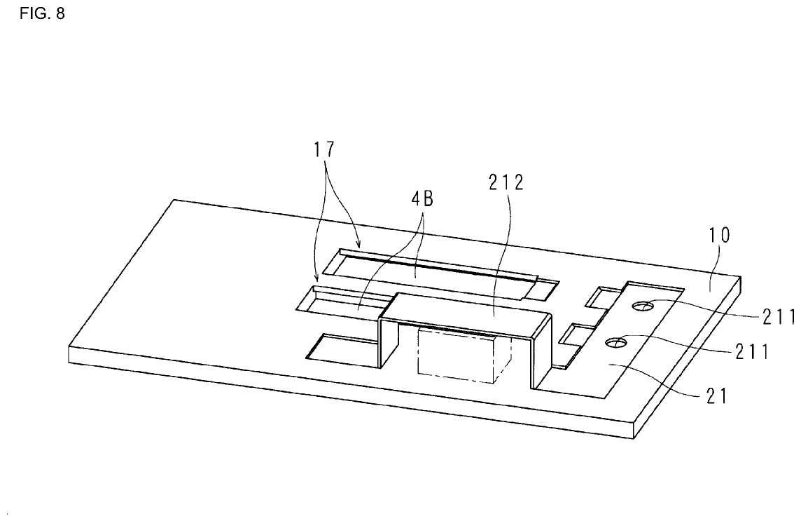

FIG. 8 is a perspective view showing the circuit structure 100 of Embodiment 2, in which a portion of the circuit structure 100 is omitted. In FIG. 8, the relays 3, the second through hole 12, and the screws 50 are not shown for the sake of convenience.

In the circuit structure 100 of Embodiment 2, as described above, the first busbar 21 includes the bent portion 212, which is spaced apart from the one surface of the insulating plate member 10 at a predetermined interval, and therefore, for example, in the case where an obstacle (see an object indicated by dot-and-dash lines in FIG. 8) or the like is present on the one surface of the insulating plate member 10, the first busbar 21 can be installed in a state of circumventing the obstacle.

At the time of assembly, screws 50 are inserted through the through holes 311 of the first terminals 31 of the relays 3, and are screwed to nuts 51 after passing through the through holes 211 of the first busbar 21 and the through holes 42 of the first heat dissipation plate member 4A. In addition, other screws 50 are inserted through the through holes 321 of the second terminals 32 of the relays 3, and are screwed to nuts 51 after passing through the through holes 221 of the second busbars 22 and the through holes 43 of the second heat dissipation plate members 4B.

At this time, the first terminals 31 of the relays 3 are electrically connected to the first busbar 21, and the first busbar 21 comes into contact with the first heat dissipation plate member 4A. Also, the second terminals 32 of the relays 3 are electrically connected to the second busbars 22, and the second busbars 22 come into contact with the second heat dissipation plate members 4B.

With the circuit structure 100 of Embodiment 2 configured as described above, when the relays 3 radiate heat during the operation, the heat is transferred to the first busbar 21 and the second busbars 22 via the first terminals 31 and the second terminals 32, respectively.

Since the first heat dissipation plate member 4A is in contact with the first busbar 21, the heat transferred to the first busbar 21 is transferred to the first heat dissipation plate member 4A and is dissipated from the one surface of the first heat dissipation plate member 4A that is air-cooled. Also, since the second heat dissipation plate members 4B are in contact with the second busbars 22, the heat transferred to the second busbars 22 is transferred to the second heat dissipation plate members 4B and is dissipated from the one surfaces of the second heat dissipation plate members 4B that are air-cooled. Accordingly, heat radiated by the relays 3 can be efficiently dissipated.

Furthermore, a part of the heat transferred to the first heat dissipation plate member 4A via the first busbar 21 and the second busbars 22 is dissipated from the other surface of the first heat dissipation plate member 4A that is air-cooled through the second through hole 12.

In the circuit structure 100 of Embodiment 2, the first heat dissipation plate member 4A is connected to the first terminals 31, which radiate a larger amount of heat than the second terminals 32, via the first busbars 21, and the second heat dissipation plate members 4B are connected to the second terminals 32 via the second busbars 22. Moreover, the first heat dissipation plate member 4A is larger in size than the second heat dissipation plate members 4B. Accordingly, heat radiated by the first terminals 31, which radiate a larger amount of heat than the second terminals 32 during the operation of the relays 3, can be predominantly dissipated, thus making it possible to more efficiently dissipate heat radiated by the relays 3.

With the configuration above, there is no need to increase the width or thickness of the busbar in order to improve the heat dissipation properties of the busbar. Accordingly, the size of the circuit structure 100 can be reduced, and the manufacturing cost of the circuit structure 100 can be reduced.

### Modified Example 1

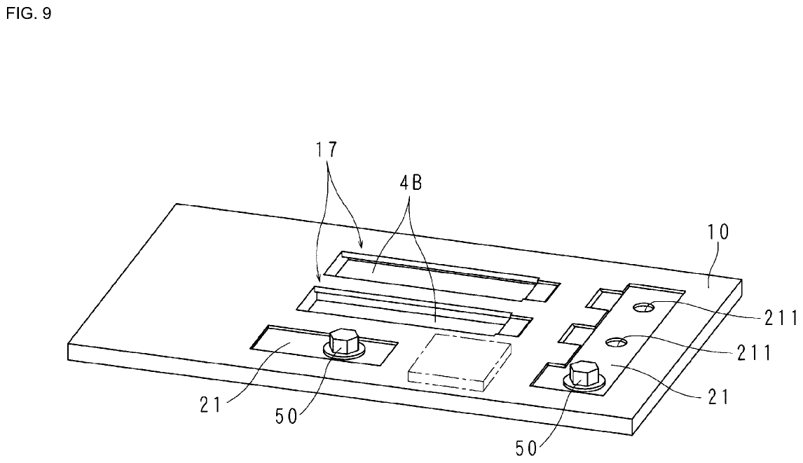

FIG. 9 is a perspective view showing Modified Example 1 of the circuit structure 100 of Embodiment 2. In FIG. 9, the relays 3, the second through hole 12, and the second busbars 22 are not shown for the sake of convenience.

In the description above, in the circuit structure 100, the first busbar 21 includes the bent portion 212, which is spaced apart from the one surface of the insulating plate member 10 at a predetermined interval, and therefore, even in the case where an obstacle (see an object indicated by dot-and-dash lines in FIG. 8) or the like is present on the one surface of the insulating plate member 10, the first busbar 21 can be installed in a state of circumventing the obstacle.

Meanwhile, in the circuit structure 100 according to Modified Example 1, the first busbar 21 does not include the bent portion 212, and is divided into two portions by removing a portion corresponding to the bent portion 212.

However, as described above, the first heat dissipation plate member 4A has electric conductivity, and both of the two portions of the divided first busbar 21 are in contact with the first heat dissipation plate member 4A and are also electrically connected to the first heat dissipation plate member 4A. Accordingly, even when the first busbar 21 is divided into two portions due to the bent portion 212 being removed, the separate portions are electrically connected to each other via the first heat dissipation plate member 4A, and thus there is no problem.

Therefore, with the circuit structure 100 according to Modified Example 1, it is possible to address an obstacle (see an object indicated by dot-and-dash lines in FIG. 9) present on the one surface of the insulating plate member 10 using a simpler configuration in which the bent portion 212 is removed.

### Modified Example 2

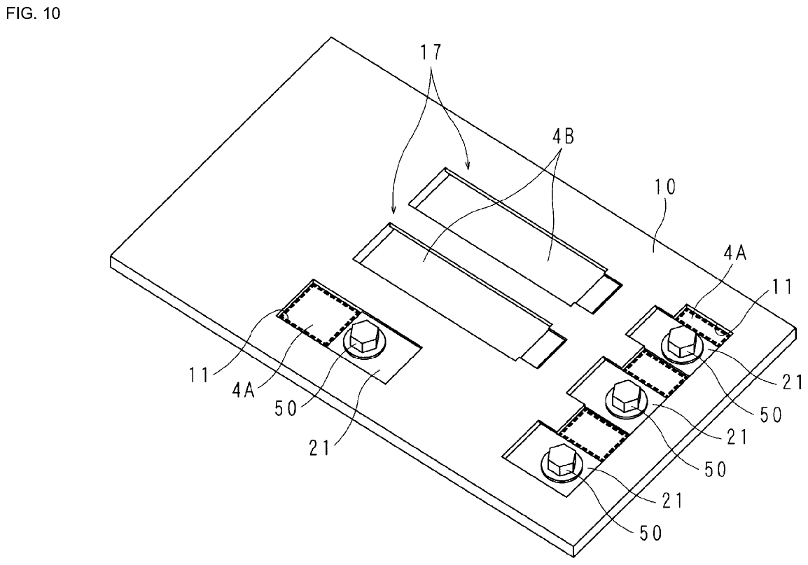

FIG. 10 is a perspective view showing Modified Example 2 of the circuit structure 100 of Embodiment 2. In FIG. 10, the relays 3, the second through hole 12, and the second busbars 22 are not shown for the sake of convenience.

In the description of Modified Example 1 above, the circuit structure 100 has a simpler configuration in which the bent portion 212 is removed.

Meanwhile, in the circuit structure 100 according to Modified Example 2, the first busbar 21 does not include the bent portion 212, and is divided into three or more portions. For example, the first busbar 21 is divided into four portions including portions connected to the first terminals 31 of the relays 3, and these portions are scattered at predetermined intervals. Thus, predetermined regions (see regions surrounded by broken lines in FIG. 10) of the first heat dissipation plate member 4A are exposed from the one surface of the insulating plate member 10 through the first through hole 11.

However, as described above, the first heat dissipation plate member 4A has electric conductivity, and the portions of the first busbar 21 are in contact with the first heat dissipation plate member 4A and are also electrically connected to the first heat dissipation plate member 4A. Accordingly, the portions of the first busbar 21 are electrically connected to each other via the first heat dissipation plate member 4A, and thus there is no problem.

Accordingly, in the circuit structure 100 according to Modified Example 2, portions of the first busbar 21 corresponding to the exposed regions of the first heat dissipation plate member 4A are removed. Therefore, the weight and the cost of the circuit structure 100 can be reduced.

Note that there is no limitation to the configurations above, and a configuration is also possible in which both of the first terminals 31 of the relays 3 are directly connected to the first heat dissipation plate member 4A, and the first busbar 21 is omitted.

Components that are identical to those of Embodiment 1 are given the same reference numerals, and specific descriptions are omitted.

The technical features (structural requirements) described in Embodiments 1 and 2 can be combined with each other, and the combinations can establish new technical features.

The embodiments disclosed herein are exemplary in all respects, and should be construed as being not limitative. The scope of the present disclosure is indicated by the scope of the appended claims rather than the above description, and all changes that fall within the same essential spirit as the scope of the claims are intended to be included therein.

1. A circuit structure that is for a vehicle and includes a circuit element having a plurality of terminals, the circuit structure comprising:
an insulating plate member, the circuit element being mounted on one surface of the insulating plate member; and
a first heat dissipation plate member provided on the other surface of the insulating plate member,
wherein the insulating plate member is provided with a first through hole in which a first busbar connected to a first terminal of the circuit element is housed, and
the first busbar is in contact with the first heat dissipation plate member.

2. The circuit structure according to claim 1,
wherein the insulating plate member is provided with a second through hole, and
the first heat dissipation plate member is exposed from the one surface side of the insulating plate member through the second through hole.

3. The circuit structure according to claim 1, wherein the insulating plate member is provided with a recessed portion in which a second busbar connected to a second terminal of the circuit element is installed, on the one surface.

4. The circuit structure according to claim 3,
wherein the second busbar is provided with a connection through hole used for connection with the second terminal,
a bottom of the recessed portion is provided with a third through hole at a position corresponding to the connection through hole,
a rib provided along an edge of the third through hole protrudes from the other surface of the insulating plate member, and
the first heat dissipation plate member is provided with a fitting through hole to which the rib is internally fitted.

5. The circuit structure according to claim 3, wherein the first terminal radiates a larger amount of heat than the second terminal during an operation of the circuit element.

6. The circuit structure according to claim 1,
wherein the insulating plate member is provided with a fourth through hole in which a second busbar connected to a second terminal of the circuit element is housed,
a second heat dissipation plate member that comes into contact with the second busbar is housed in the fourth through hole, and
an insulating thread is interposed between the first heat dissipation plate member and the second heat dissipation plate member on the other surface of the insulating plate member.

7. The circuit structure according to claim 6,
wherein the first terminal radiates a larger amount of heat than the second terminal during an operation of the circuit element, and
the first heat dissipation plate member is larger in size than the second heat dissipation plate member.

8. The circuit structure according to claim 1, wherein the first heat dissipation plate member has electric conductivity.

9. The circuit structure according to claim 2, wherein the insulating plate member is provided with a recessed portion in which a second busbar connected to a second terminal of the circuit element is installed, on the one surface.

10. The circuit structure according to claim 4, wherein the first terminal radiates a larger amount of heat than the second terminal during an operation of the circuit element.

11. The circuit structure according to claim 2,
wherein the insulating plate member is provided with a fourth through hole in which a second busbar connected to a second terminal of the circuit element is housed,
a second heat dissipation plate member that comes into contact with the second busbar is housed in the fourth through hole, and
an insulating thread is interposed between the first heat dissipation plate member and the second heat dissipation plate member on the other surface of the insulating plate member.

12. The circuit structure according to claim 2, wherein the first heat dissipation plate member has electric conductivity.

13. The circuit structure according to claim 3, wherein the first heat dissipation plate member has electric conductivity.

14. The circuit structure according to claim 4, wherein the first heat dissipation plate member has electric conductivity.

15. The circuit structure according to claim 5, wherein the first heat dissipation plate member has electric conductivity.

16. The circuit structure according to claim 6, wherein the first heat dissipation plate member has electric conductivity.

17. The circuit structure according to claim 7, wherein the first heat dissipation plate member has electric conductivity.
